(19) United States
(12) Patent Application Publication
(10) Pub. No.: US 2012/0249120 A1
(43) Pub. Date: Oct. 4, 2012

(54) CURRENT LOOP DETECTION SYSTEM AND CURRENT LOOP DETECTION METHOD THEREOF

(75) Inventors: Pi-Chuan LO, New Taipei City (TW); Shu-Li CHANG, Hsinchu City (TW)

(73) Assignee: INSTITUTE FOR INFORMATION INDUSTRY, Taipei (TW)

(21) Appl. No.: 13/154,372

(22) Filed: Jun. 6, 2011

(30) Foreign Application Priority Data
Mar. 30, 2011 (TW) 100110946

(51) Int. Cl. G01R 19/00

(52) U.S. Cl. 324/76.11

(57) ABSTRACT

A current loop detection system and a current loop detection method thereof are provided. The current loop detection system includes a characteristic load, a current measuring apparatus and a user apparatus. The characteristic load connects to a current loop electrically, and generates a current characteristic waveform while operating. The current measuring apparatus connects to a current source electrically. The user apparatus connects to the current measuring apparatus via a first connection. The current measuring apparatus transmits an output current waveform of the current source to the user apparatus via the first connection. The user apparatus determines that the output current waveform corresponds to the current characteristic waveform and, according to a result of the determination, determines that the current source connects to the current loop electrically.

### PRIORITY

This application claims priority to Taiwan Patent Application No. 100110946 filed on Mar. 30, 2011, which is hereby incorporated herein by reference in its entirety.

### FIELD

The present invention relates to a current loop detection system and a current loop detection method thereof. More particularly, the current loop detection system and the current loop detection method thereof of the present invention can be used to determine a correspondence relationship between a current source and a current loop.

### BACKGROUND

Electric engineering is now indispensable to people's lives. With enhancement of the awareness of energy-saving and environmental protection, how to utilize the electric power resources more efficiently has become an important topic. Nowadays, a preferred means to manage energy sources is to gradually upgrade the existing electric power infrastructure into the Advanced Meter Infrastructure (AMI). The main reasons lie in that, through exchange of data such as the electric power utilization status, the AMI can accomplish the function of automatic power source management for energy-saving purpose. In order to exchange data in the AMI under the existing hardware architecture, the power line communication (PLC) technology has been developed.

Because the PLC technology makes it possible to transmit data through the existing power lines, the cost of additional wiring can be significantly decreased. For this reason, the PLC technology has become one of the most commonly used communication modes in the AMI. However, because of the nature of the PLC, power line communications are liable to interference, which is especially the case for long-distance communications across different current sources. This degrades the signal quality to a great extent. Therefore, the correspondence relationships between current loops and current sources must be clearly known before PLC-related technologies are used in the AMI.

Currently, correspondence relationships between current sources and current loops are determined primarily through manual detection or through use of PLC testing instruments. For the manual detection, a technician must be sent to locations where electric meters are distributed in the current loops so that field surveys and detections can be carried out with reference to the blueprints of line diagrams used when the current loops were constructed. However, due to different work site conditions, difficulties may exist in the manual detection; for example, it is possible that the lines are arranged in a mess, buildings may present as barriers or actual wirings are inconsistent with the blueprints of line diagrams.

Additionally, PLC testing instruments may be used to determine whether a current source and a current loop correspond to each other according to the communication quality. However, in this case, if the transmission distance of the PLC is too long, the signal will be attenuated to cause failure of the communication, thus lowering the accuracy of the detection. Moreover, the PLC testing instruments can only perform point-to-point detections and also are very expensive, so it is impossible to perform effective detections at a low cost by use of the PLC testing instruments.

Accordingly, an urgent need exists in the art to provide a solution that can determine a correspondence relationship between a current source and a current loop efficiently and correctly at a low cost so that the PLC can be properly employed in the AMI.

### SUMMARY

To solve the aforesaid problems generated when a correspondence relationship between a current source and a current loop is determined through the manual detection or through use of the PLC testing instruments, certain embodiments of the present invention provide a current loop detection system and a current loop detection method thereof. The current loop detection system and the current loop detection method thereof determine the correspondence relationship between the current source and the current loop mainly by additionally providing a characteristic load at the current loop end and measuring a current waveform of the characteristic load at the current source end.

To achieve the aforesaid objective, certain embodiments of the present invention provide a current loop detection method for use in a current loop detection system. The current loop detection system comprises a characteristic load, a current measuring apparatus and a user apparatus. The current measuring apparatus connects to the user apparatus via a first connection. The current loop detection method comprises the following steps of: (a) enabling the characteristic load to connect to a current loop electrically, wherein the characteristic load generates a current characteristic waveform while the characteristic load operates; (b) enabling the current measuring apparatus to connect to a current source electrically and to transmit an output current waveform of the current source to the user apparatus via the first connection; (c) enabling the user apparatus to determine that the output current waveform corresponds to the current characteristic waveform; and (d) enabling the user apparatus to determine that the current source connects to the current loop electrically according to a result of the step (c).

To achieve the aforesaid objective, certain embodiments of the present invention also provide a current loop detection system. The current loop detection system comprises a characteristic load, a current measuring apparatus and a user apparatus. The characteristic load connects to a current loop electrically, and generates a current characteristic waveform while the characteristic load operates. The current measuring apparatus connects to a current source electrically. The user apparatus connects to the current measuring apparatus via a first connection. The current measuring apparatus transmits an output current waveform of the current source to the user apparatus via the first connection. The user apparatus determines that the output current waveform corresponds to the current characteristic waveform and, according to a result of the determination, determines that the current source connects to the current loop electrically.

With the technical features disclosed above, the current loop detection system and the current loop detection method thereof of the present invention can determine whether the output current waveform of the current source corresponds to the current characteristic waveform generated by the characteristic load when operating. If the answer is “yes”, it means that the current source connects to the current loop electrically.

The detailed technology and preferred embodiments implemented for the subject invention are described in the following paragraphs accompanying the appended drawings for people skilled in this field to well appreciate the features of the claimed invention. It is understood that the features mentioned hereinbefore and those to be commented on hereinafter may be used not only in the specified combinations, but also in other combinations or in isolation, without departing from the scope of the present invention.

### BRIEF DESCRIPTION OF THE DRAWINGS

FIG. 1A is a schematic view of a first embodiment of the present invention;

FIG. 1B is a schematic view of a current waveform of a current source according to the first embodiment of the present invention;

FIG. 1C is a schematic view of a current waveform of a characteristic load according to the first embodiment of the present invention;

FIG. 1D is a schematic view of a current waveform of the current source according to the first embodiment of the present invention;

FIG. 2 is a schematic view of a second embodiment of the present invention;

FIG. 3 is a schematic view of a third embodiment of the present invention;

FIG. 4A is a schematic view of a fourth embodiment of the present invention;

FIG. 4B is a schematic view of current waveforms of current sources according to the fourth embodiment of the present invention;

FIG. 4C is a schematic view of a current waveform of a characteristic load according to the fourth embodiment of the present invention;

FIG. 4D is a schematic view of current waveforms of the current sources according to the fourth embodiment of the present invention;

FIG. 5 is a flowchart of a current loop detection method according to a fifth embodiment of the present invention;

FIG. 6 is a flowchart of a current loop detection method according to a sixth embodiment of the present invention; and

FIG. 7 is a flowchart of a current loop detection method according to a seventh embodiment of the present invention.

### DETAILED DESCRIPTION

In the following descriptions, the present invention will be explained with reference to example embodiments thereof. However, these example embodiments are not intended to limit the present invention to any specific example, embodiment, environment, applications or particular implementations described in these embodiments. Therefore, description of these example embodiments is only for purpose of illustration rather than to limit the present invention. It shall be appreciated that, in the following embodiments and the attached drawings, elements not directly related to the present invention are omitted from depiction.

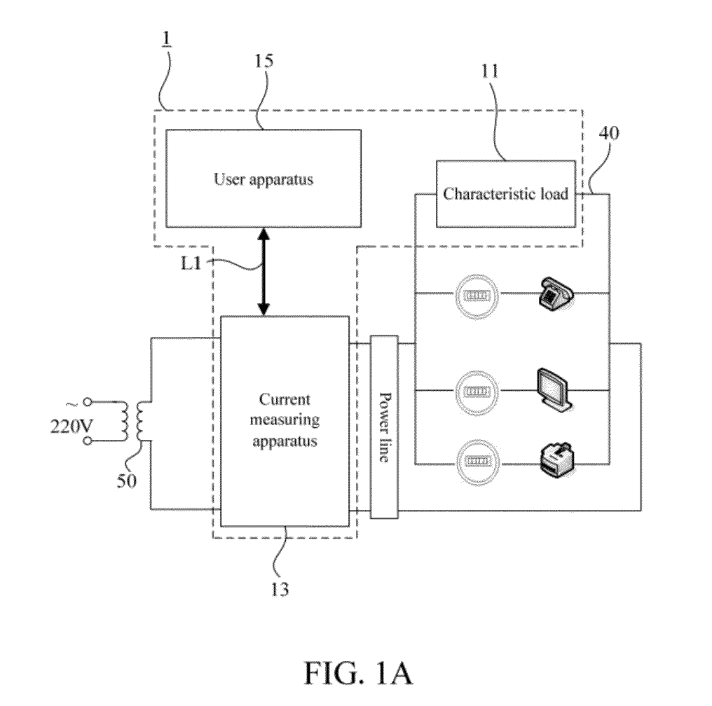

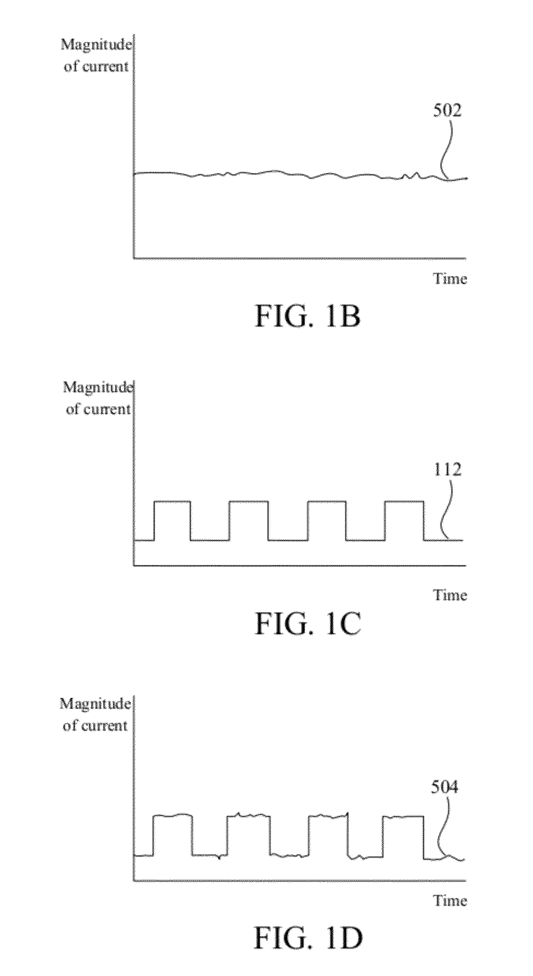

Firstly, referring to FIG. 1A, there is shown a schematic view of a current loop detection system 1 according to a first embodiment of the present invention. The current loop detection system 1 comprises a characteristic load 11, a current measuring apparatus 13 and a user apparatus 15. The characteristic load 11 connects to a current loop 40 electrically, the current measuring apparatus 13 connects to a current source 50 electrically, and the user apparatus 15 connects to the current measuring apparatus 13 via a first connection L1. The current source 50 is a piece of equipment (e.g., a transformer) for supplying a current, and the current loop 40 comprises therein various electric appliances normally used. Functions and interactions of the individual elements will be described in detail hereinafter.

Referring to FIG. 1B, there is shown a schematic view of a current waveform of the current source 50 in a stable service status as measured by the current measuring apparatus 13. In detail, a user can firstly utilize the user apparatus 15 to obtain, from the current measuring apparatus 13 and via the first connection L1, an output current waveform 502 supplied by the current source 50 in the stable service status.

In other words, when connecting to the current source 50 electrically, the current measuring apparatus 13 can measure an output current of the current source 50 in the stable service status and transmit the output current waveform 502 of the output current to the user apparatus 15 via the first connection L1 so that the current waveform of the current source 50 in the stable service status can be known by the user. It shall be particularly appreciated that, in the normal service status, variations of the total current outputted by the current source 50 shall tend to become stable temporarily, and in this case, the output current waveform 502 of the current received by the user apparatus 15 from the current source 50 shall approximate to a straight line.

Referring next to FIG. 1C together, there is shown a current characteristic waveform 112 generated by the characteristic load 11 when operating. Specifically, after the testing settings at the current source 50 end have been set, the characteristic load 11 starts to operate and generates the current characteristic waveform 112 when operating. It shall be particularly appreciated that, the characteristic load 11 can operate based on the current characteristic waveform 112 after a predetermined period. The current characteristic waveform 112 has a shape that is intended for identification. In the first embodiment, the current characteristic waveform 112 is a square waveform; however, this is not intended to limit the shape of the current characteristic waveform 112, and in other embodiments, the current characteristic waveform 112 may be one of a sine waveform, a triangle waveform, a pulse waveform and a sawtooth waveform, or any other waveform that can be used for identification purpose.

Then, in the first embodiment, the user can know whether a correspondence relationship exists between the current source 50 and the current loop 40 by measuring the current status of the current source 50 by the current measuring apparatus 13. Referring to FIG. 1D together, there is shown an output current waveform 504 measured by the current measuring apparatus 13 and received by the user apparatus 13 via the first connection L1 continuously.

Specifically, after the characteristic load 11 has started to operate, the user apparatus 15 determines whether the output current waveform 504 corresponds to (is similar to or consistent with) the current characteristic waveform 112. Further speaking, assume that the current characteristic waveform 112 is a square waveform. Then, if the output current waveform 504 that is measured also changes into a similar square waveform, it means that the current characteristic waveform 112 generated by the characteristic load 11 in the current loop 40 to which it is connected regularly affects the output current of the current source 50, so the output current waveform 504 of the current source 50 corresponds to the current characteristic waveform 112. From this, the user apparatus 15 can determine that the current source 50 and the current loop 40 electrically connect to each other and are located in the same current loop.

On the other hand, if the output current waveform 504 and the current characteristic waveform 112 do not correspond to each other, it means that the output current of the current source 50 is not affected by the current characteristic waveform generated by the characteristic load 11. Then, it can be known that the current source 50 and the current loop 40 do not electrically connect to each other (i.e., the current source 50 and the current loop 40 are located in different current loops).

It shall be particularly appreciated that, because existence of the correspondence relationship between the current source 50 and the current loop 40 can still not be determined at an initial stage of the test, a generalized power line is used as a medium between the current source 50 and the current loop 40 in the drawing; however, this is not intended to limit the connection status between the current source 50 and the current loop 40. In addition, the user apparatus 15 may be a personal computer (PC), a smart phone, a personal digital assistant (PDA), or any other apparatus with calculation and display capabilities. The first connection L1 may be implemented as a wireless connection (including the infrared communication, the Bluetooth, a wireless network and the like) or a wired connection.

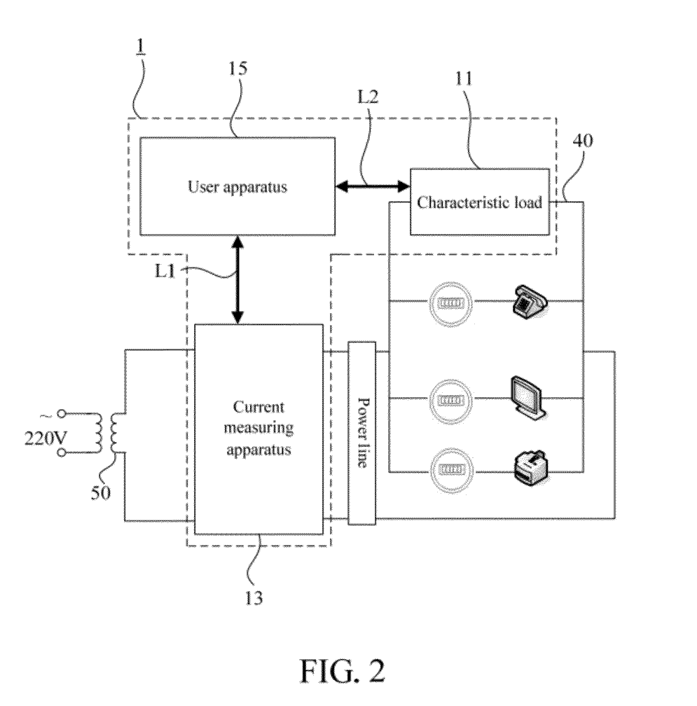

Referring to FIG. 2, there is shown a schematic view of a second embodiment of the present invention. Elements used in the second embodiment are identical to those in the first embodiment, so functions of those elements will not be further described herein. It shall be particularly emphasized that, the second embodiment differs from the first embodiment in that, the user apparatus 15 connects to the characteristic load 11 via a second connection L2; i.e., the user apparatus 15 can communicate with the characteristic load 11 via the second connection L2.

Further speaking, in the first embodiment, the characteristic load 11 automatically starts to operate after the predetermined period. However, in the second embodiment, the user can manually set the operation of the characteristic load 11 by means of the user apparatus 15 via the second connection L2. Furthermore, by means of the user apparatus 15, the user can decide the characteristic waveform 112 of the characteristic load 11 to be one of a sine waveform, a triangle waveform, a pulse waveform and a sawtooth waveform via the second connection L2; thus, a waveform that is easy to be identified can be chosen by the user depending on practical conditions. It shall be particularly appreciated that, the second connection L2 may be implemented as a wireless connection (including the infrared communication, the Bluetooth, a wireless network and the like) or a wired connection.

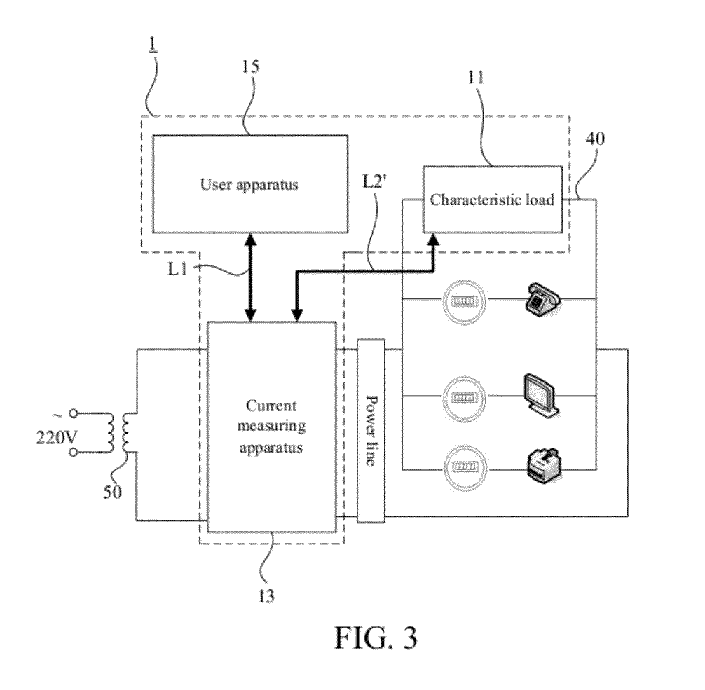

Referring to FIG. 3, there is shown a schematic view of a third embodiment of the present invention. Elements used in the third embodiment are identical to those in the first embodiment, so functions of those elements will not be further described herein. It shall be particularly emphasized that, the third embodiment differs from the first embodiment in that, the current measuring apparatus 13 connects to the characteristic load 11 via a second connection L2′; i.e., the current measuring apparatus 13 can communicate with the characteristic load 11 via the second connection L2′ so that the user apparatus 15 can communicate with the characteristic load 11 through the current measuring apparatus 13 via the first connection L1 and the second connection L2′.

Further speaking, in the first embodiment, the characteristic load 11 automatically starts to operate after the predetermined period. However, in the third embodiment, the user can utilize the user apparatus 15 to manually set the operation of the characteristic load 11 through the current measuring apparatus 13 via the first connection L1 and the second connection L2′. Furthermore, the user can also utilize the user apparatus 15 to decide the characteristic waveform 112 of the characteristic load 11 to be one of a sine waveform, a triangle waveform, a pulse waveform and a sawtooth waveform through the current measuring apparatus 13 via the first connection L1 and the second connection L2′; thus, a waveform that is easy to be identified can be chosen by the user according to practical conditions. It shall be particularly appreciated that, the second connection L2′ may be implemented as a wireless connection (including the infrared communication, the Bluetooth, a wireless network and the like) or a wired connection.

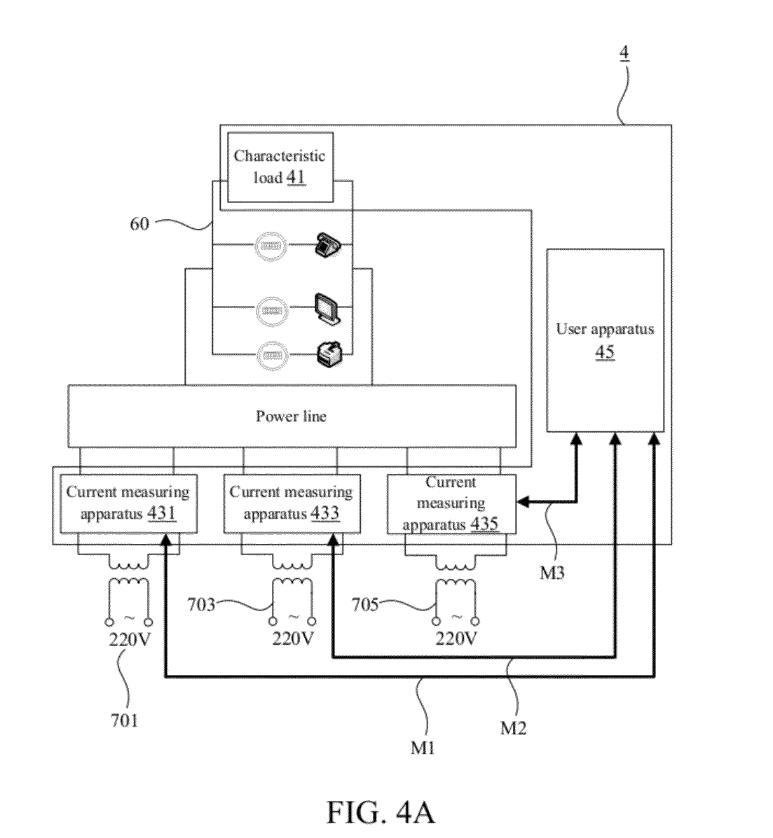

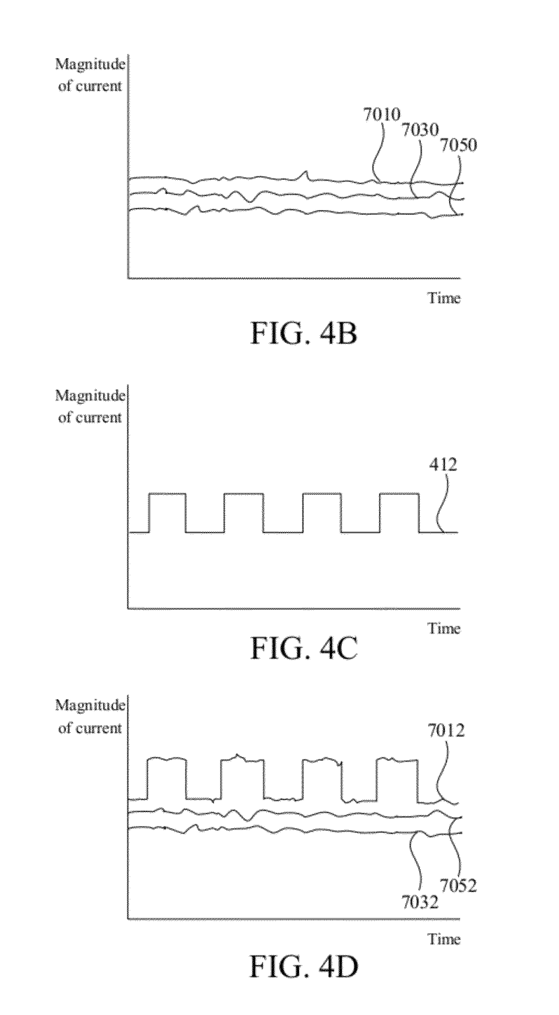

The current loop detection system of the present invention can also measure correspondence relationships of multiple groups of current sources and current loops simultaneously. Referring to FIG. 4A together, there is shown a schematic view of a current loop detection system 4 according to a fourth embodiment of the present invention. The current loop detection system 4 comprises a characteristic load 41, a plurality of current measuring apparatuses 431, 433, 435 and a user apparatus 45. The characteristic load 41 connects to a current loop 60 electrically, the current measuring apparatuses 431, 433, 435 electrically connect to a plurality of current sources 701, 703, 705 respectively, and the user apparatus 45 connects to the current measuring apparatuses 431, 433, 435 via first connections M1, M2, M3 respectively. Each of the current sources 701, 703, 705 is a piece of equipment (e.g., a transformer) for supplying a current, and the current loop 60 comprises therein various electric appliances that are normally used. Functions and interactions of the individual elements will be described in detail hereinafter.

Referring to FIG. 4B together, there is shown a schematic view of current waveforms of the current sources 701, 703, 705 in the stable service status as measured by the current measuring apparatuses 431, 433, 435 respectively. In detail, the user can firstly utilize the user apparatus 45 to obtain, from the current measuring apparatuses 431, 433, 435 and via the first connections M1, M2, M3 respectively, a plurality of output current waveforms 7010, 7030, 7050 supplied by the current sources 701, 703, 705 in the stable service status. Similarly, each of the current waveforms 7010, 7030, 7050 in the fourth embodiment may also approximate to a straight line as a result of a stable total current outputted by each of the current sources 701, 703, 705 respectively.

Referring next to FIG. 4C together, there is shown a current characteristic waveform 412 generated by the characteristic load 41 when operating. Specifically, after the testing settings at the end of each of the current sources 701, 703, 705 have been set, the characteristic load 41 starts to operate and generates the current characteristic waveform 412 when operating. Likewise, the characteristic load 41 can operate based on the current characteristic waveform 412 after a predetermined period. The current characteristic waveform 412 has a shape intended for identification. In the fourth embodiment, the current characteristic waveform 412 is a square waveform; however, this is not intended to limit the shape of the current characteristic waveform 412, and in other embodiments, the current characteristic waveform 412 may be one of a sine waveform, a triangle waveform, a pulse waveform and a sawtooth waveform, or any other waveform that can be used for identification purpose.

Then, in the fourth embodiment, the user can know a correspondence relationship between each of the current sources 701, 703, 705 and the current loop 60 by measuring the current status of each of the current sources 701, 703, 705 by each of the current measuring apparatuses 431, 433, 435. Referring to FIG. 4D together, there are shown output current waveforms 7012, 7032, 7052 that are measured by the current measuring apparatuses 431, 433, 435 and continuously received by the user apparatus 30 via the first connections M1, M2, M3 respectively.

Specifically, after the characteristic load 41 has started to operate, the user apparatus 45 determines which one of the output current waveforms 7012, 7032, 7052 corresponds to the current characteristic waveform 412. In the fourth embodiment, as shown in FIG. 4D, it is the output current waveform 7012 that corresponds to the current characteristic waveform 412. This means that the current characteristic waveform 412 generated by the characteristic load 41 in the current loop 60 to which it is connected regularly affects the current outputted by the current source 701 so that the output current waveform 7012 of the current source 701 corresponds to the current characteristic waveform 412. From this, the user apparatus 45 can determine that the current source 701 electrically connects to the current loop 60 and is located in the same current loop as the current loop 60.

On the other hand, neither of the output current waveforms 7032, 7052 corresponds to the current characteristic waveform 412, and this means that the output currents of the current sources 703, 705 are not affected by the current characteristic waveform generated by the characteristic load 41. Thereby, it can be known that neither of the current sources 703, 705 connects to the current loop 60 electrically (i.e., the current sources 703, 705 are both located in other current loops than the current loop 60).

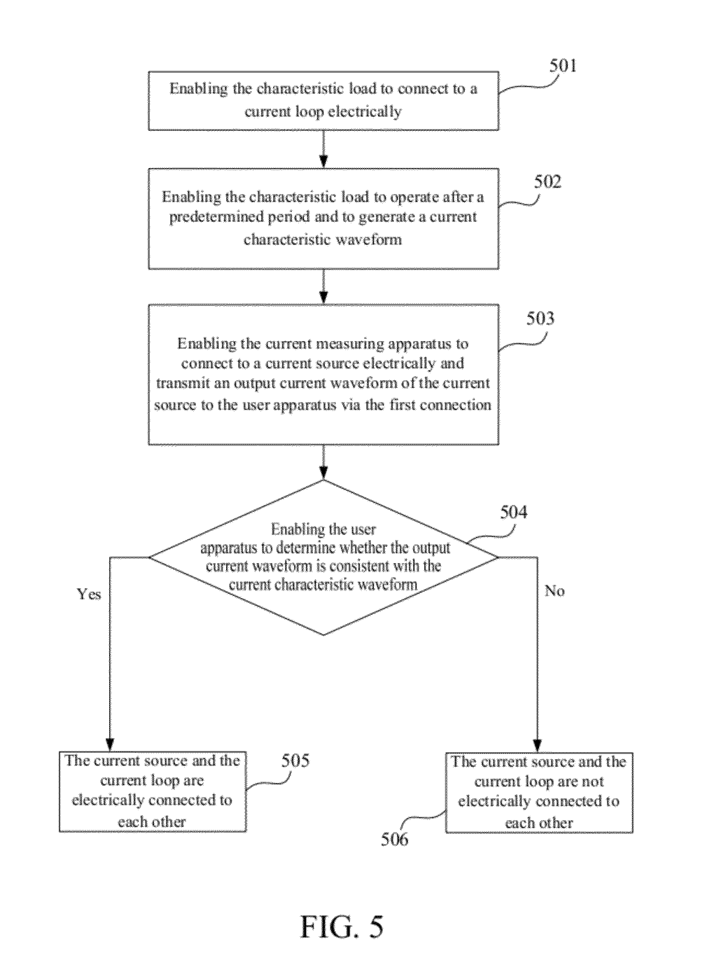

A fifth embodiment of the present invention is a current loop detection method, a flowchart of which is shown in FIG. 5. The method of the fifth embodiment is for use in a current loop detection system (e.g., the current loop detection system 1 described in the first embodiment). The current loop detection system comprises a characteristic load, a current measuring apparatus and a user apparatus. The current measuring apparatus connects to the user apparatus via a first connection. Detailed steps of the current loop detection method are described as follows.

Firstly, step 501 is executed to enable the characteristic load to connect to a current loop electrically. Then, step 502 is executed to enable the characteristic load to operate after a predetermined period. The characteristic load generates a current characteristic waveform while operating. Step 503 is executed to enable the current measuring apparatus to connect to a current source electrically and transmit an output current waveform of the current source to the user apparatus via the first connection. It shall be particularly appreciated that, the order of the step 502 may be exchanged with that of the step 503; i.e., the step 503 may be firstly executed to set the settings of the current source end, and then the step 502 is executed to activate the characteristic load to operate.

Subsequently, step 504 is executed to enable the user apparatus to determine whether the output current waveform corresponds to (is similar to or consistent with) the current characteristic waveform. If a result of the determination in the step 504 is “yes”, it means that the current characteristic waveform generated by the characteristic load in the current loop to which it is connected can regularly affect the current outputted by the current source so that the output current waveform of the current source corresponds to (is similar to or consistent with) the current characteristic waveform. Then, step 505 is executed to determine that the current source and the current loop electrically connect to each other and are located in the same current loop.

Conversely, if the result of the determination in the step 504 is “no”, it means that the current outputted by the current source is not affected by the current characteristic waveform generated by the characteristic load in the current loop to which it is connected. Then, step 506 is executed to determine that the current source and the current loop do not electrically connect to each other and are located in different current loops.

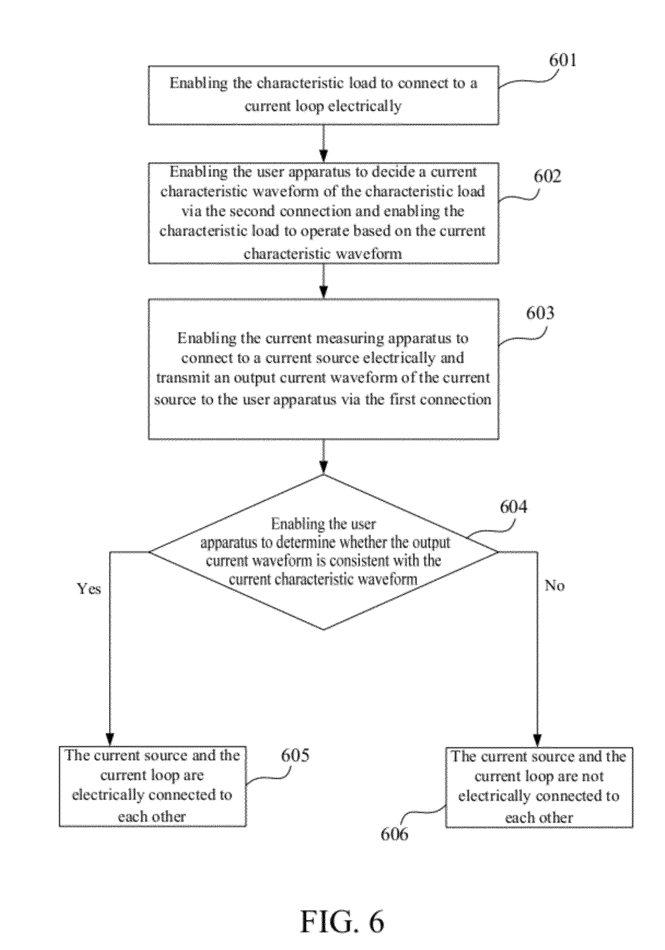

A sixth embodiment of the present invention is a current loop detection method, a flowchart of which is shown in FIG. 6. The method of the sixth embodiment is for use in a current loop detection system (e.g., the current loop detection system 1 described in the second embodiment). Likewise, the current loop detection system comprises a characteristic load, a current measuring apparatus and a user apparatus. The current measuring apparatus connects to the user apparatus via a first connection, and the user apparatus connects to the characteristic load via a second connection. Detailed steps of the current loop detection method are described as follows.

Firstly, step 601 is executed to enable the characteristic load to connect to a current loop electrically. Then, step 602 is executed to enable the user apparatus to decide a current characteristic waveform of the characteristic load via the second connection and enable the characteristic load to operate based on the current characteristic waveform. Step 603 is executed to enable the current measuring apparatus to connect to a current source electrically and transmit an output current waveform of the current source to the user apparatus via the first connection. It shall be particularly appreciated that, the order of the step 602 may also be exchanged with that of the step 603; i.e., the step 603 may be firstly executed to set the settings of the current source end, and then the step 602 is executed to activate the characteristic load to operate.

Subsequently, step 604 is executed to enable the user apparatus to determine whether the output current waveform corresponds to (is similar to or consistent with) the current characteristic waveform. If a result of the determination in the step 604 is “yes”, it means that the current characteristic waveform generated by the characteristic load in the current loop to which it is connected can regularly affect the current outputted by the current source so that the output current waveform of the current source corresponds to (is similar to or consistent with) the current characteristic waveform. Then, step 605 is executed to determine that the current source and the current loop electrically connect to each other and are located in the same current loop.

Conversely, if the result of the determination in the step 604 is “no”, it means that the current outputted by the current source is not affected by the current characteristic waveform generated by the characteristic load in the current loop to which it is connected. Then, step 606 is executed to determine that the current source and the current loop do not electrically connect to each other and are located in different current loops.

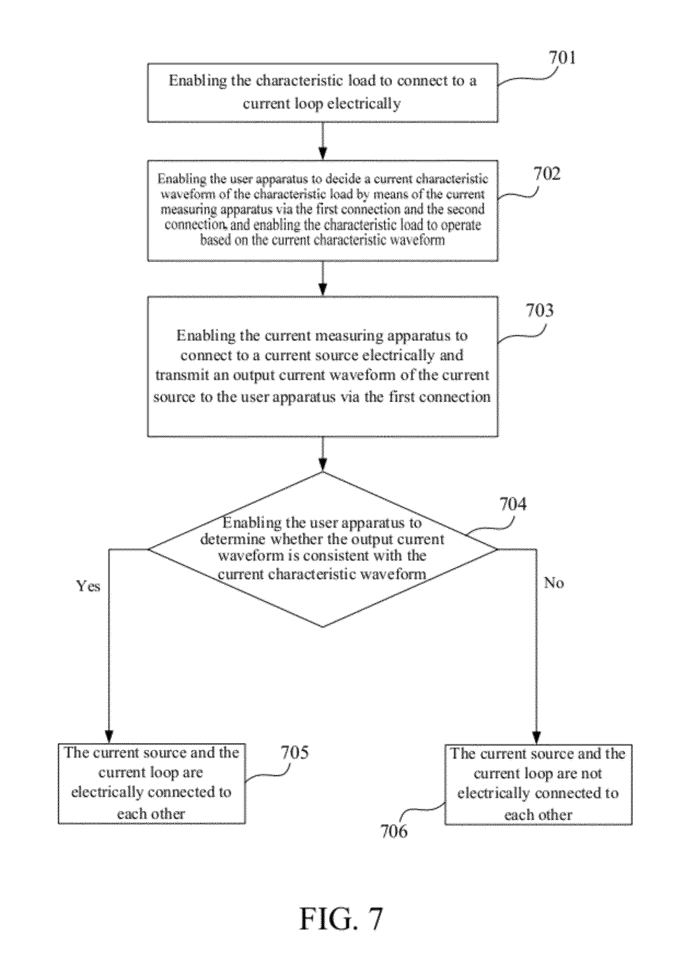

A seventh embodiment of the present invention is a current loop detection method, a flowchart of which is shown in FIG. 7. The method of the seventh embodiment is for use in a current loop detection system (e.g., the current loop detection system 1 described in the third embodiment). Likewise, the current loop detection system comprises a characteristic load, a current measuring apparatus and a user apparatus. The current measuring apparatus connects to the user apparatus via a first connection, and connects to the characteristic load via a second connection. Detailed steps of the current loop detection method are described as follows.

Firstly, step 701 is executed to enable the characteristic load to connect to a current loop electrically. Then, step 702 is executed to enable the user apparatus to decide a current characteristic waveform of the characteristic load by means of the current measuring apparatus via the first connection and the second connection, and enable the characteristic load to operate based on the current characteristic waveform. Step 703 is executed to enable the current measuring apparatus to connect to a current source electrically and transmit an output current waveform of the current source to the user apparatus via the first connection. It shall be particularly appreciated that, the order of the step 702 may be exchanged with that of the step 703; i.e., the step 703 may be firstly executed to set the settings of the current source end, and then the step 702 is executed to activate the characteristic load to operate.

Subsequently, step 704 is executed to enable the user apparatus to determine whether the output current waveform corresponds to (is similar to or consistent with) the current characteristic waveform. If a result of the determination in the step 704 is “yes”, it means that the current characteristic waveform generated by the characteristic load in the current loop to which it is connected can regularly affect the current outputted by the current source so that the output current waveform of the current source corresponds to (is similar to or consistent with) the current characteristic waveform. Then, step 705 is executed to determine that the current source and the current loop electrically connect to each other and are located in the same current loop.

Conversely, if the result of the determination in the step 704 is “no”, it means that the current outputted by the current source is not affected by the current characteristic waveform generated by the characteristic load in the current loop to which it is connected. Then, step 706 is executed to determine that the current source and the current loop do not electrically connect to each other and are located in different current loops.

According to the above descriptions, the current loop detection system and the current loop detection method of the present invention can determine a correspondence relationship between a current source and a current loop effectively and correctly at a low cost. In this way, the disadvantages of the conventional manual detection or the conventional method of employing PLC testing instruments for detection can be easily overcome, and detection of the current loop can be accomplished more efficiently.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A current loop detection method for use in a current loop detection system, the current loop detection system comprising a current measuring apparatus, a characteristic load and an user apparatus, the current measuring apparatus connecting to the user apparatus via a first connection, the current loop detection method comprising the steps of:
(a) enabling the characteristic load to connect to a current loop electrically, wherein the characteristic load generates a current characteristic waveform while the characteristic load operates;
(b) enabling the current measuring apparatus to connect to a current source electrically and to transmit an output current waveform of the current source to the user apparatus via the first connection;
(c) enabling the user apparatus to determine that the output current waveform corresponds to the current characteristic waveform; and
(d) enabling the user apparatus to determine that the current source connects to the current loop electrically according to a result of the step (c).

2. The current loop detection method as claimed in claim 1, wherein the step (a) further comprises the step of:
(a1) enabling the characteristic load to operate based on the current characteristic waveform after a predetermined period.

3. The current loop detection method as claimed in claim 1, wherein the user apparatus connects to the characteristic load via a second connection, and the user apparatus decides the current characteristic waveform of the characteristic load via the second connection.

4. The current loop detection method as claimed in claim 1, wherein the current measuring apparatus connects to the characteristic load via a second connection, and the user apparatus decides the current characteristic waveform of the characteristic load through the current measuring apparatus via the first connection and the second connection.

5. The current loop detection method as claimed in claim 1, wherein the current characteristic waveform is one of a square waveform, a sine waveform, a triangle waveform, a pulse waveform and a sawtooth waveform.

6. A current loop detection system, comprising:
a characteristic load, being configured to connect to a current loop electrically, wherein the characteristic load generates a current characteristic waveform while the characteristic load operates;
a current measuring apparatus, being configured to connect to a current source electrically; and
an user apparatus, being configured to connect to the current measuring apparatus via a first connection;
wherein the current measuring apparatus transmits an output current waveform of the current source to the user apparatus via the first connection, and the user apparatus determines that the current source connects to the current loop electrically according to a result of the determination of the output current waveform corresponding to the current characteristic waveform.

7. The current loop detection system as claimed in claim 6, wherein the characteristic load operates based on the current characteristic waveform after a predetermined period.

8. The current loop detection system as claimed in claim 6, wherein the user apparatus connects to the characteristic load via a second connection, and the user apparatus decides the current characteristic waveform of the characteristic load via the second connection.

9. The current loop detection system as claimed in claim 6, wherein the current measuring apparatus connects to the characteristic load via a second connection, and the user apparatus decides the current characteristic waveform of the characteristic load through the current measuring apparatus via the first connection and the second connection.

10. The current loop detection system as claimed in claim 6, wherein the current characteristic waveform is one of a square waveform, a sine waveform, a triangle waveform, a pulse waveform and a sawtooth waveform.
